(19) United States
(12) Patent Application Publication
(10) Pub. No.: US 2025/0183855 A1
(43) Pub. Date: Jun. 5, 2025

(54) DISTORTION COMPENSATION DEVICE, DISTORTION COMPENSATION METHOD, AND TRANSMISSION DEVICE

(71) Applicant: Mitsubishi Electric Corporation, Tokyo (JP)

(72) Inventors: Ao YAMASHITA, Tokyo (JP); Hiroto SAKAKI, Tokyo (JP); Hideyuki NAKAMIZO, Tokyo (JP)

(73) Assignee: Mitsubishi Electric Corporation, Tokyo (JP)

(21) Appl. No.: 19/045,457

(22) Filed: Feb. 4, 2025

Related U.S. Application Data
(63) Continuation of application No. PCT/JP2022/030351, filed on Aug. 9, 2022.

(51) Int. Cl. H03F 1/32

(52) U.S. Cl. CPC H03F 1/32

(57) ABSTRACT

A distortion compensation device includes: an amplification target signal acquiring unit that acquires an amplification target signal to which power amplification by a power amplifier is performed; and an operation status signal acquiring unit that acquires an operation status signal indicating an operation status of the power amplifier. In addition, the distortion compensation device includes a distortion compensation unit that estimates a signal in which distortion is added to the amplification target signal acquired by the amplification target signal acquiring unit as a predistortion signal for compensating distortion generated in the amplification target signal after power amplification by the power amplifier on the basis of the amplification target signal acquired by the amplification target signal acquiring unit and the operation status signal acquired by the operation status signal acquiring unit, and outputs the predistortion signal to the power amplifier.

### CROSS REFERENCE TO RELATED APPLICATION

This application is a Continuation of PCT International Application No. PCT/JP2022/030351, filed on Aug. 9, 2022, which is hereby expressly incorporated by reference into the present application.

### TECHNICAL FIELD

The present disclosure relates to a distortion compensation device, a distortion compensation method, and a transmission device.

### BACKGROUND ART

There is a transmission device including a power amplifier that amplifies power of a transmission signal. A non-linear characteristic of the power amplifier may generate distortion in an amplification target signal after power amplification by the power amplifier. For example, Non-Patent Literature 1 discloses a distortion compensation device for compensating distortion generated in a transmission signal after power amplification by a power amplifier. The distortion compensation device includes a distortion compensation unit that gives a transmission signal to be power-amplified to a neural network (hereinafter, referred to as a “learning model”) and acquires, from the learning model, a predistortion signal for compensating distortion generated in the transmission signal after power amplification by the power amplifier. The distortion compensation unit outputs the predistortion signal to the power amplifier as the transmission signal.

### CITATION LIST

### Non-Patent Literature

Non-Patent Literature 1: Slim Boumaiza, and Farouk Mkadem, “Wideband RF Power Amplifier Predistortion using Real-Valued Time-Delay Neural Networks”, European Microwave Conference (EuMC), 2009.

### SUMMARY OF INVENTION

### Technical Problem

By change of an operation status of a power amplifier, distortion generated in a transmission signal after power amplification by the power amplifier changes. Examples of the operation status of the power amplifier include an ambient temperature of the power amplifier, a carrier frequency of the transmission signal, and a bias voltage of the power amplifier.

In the distortion compensation device disclosed in Non-Patent Literature 1, an operation status of the power amplifier at the time of training of the learning model may be different from an operation status of the power amplifier when the distortion compensation unit acquires the predistortion signal from the learning model. As described above, when there is a difference in the operation status of the power amplifier, there is a difference in the distortion generated in the transmission signal after power amplification by the power amplifier. For this reason, even when the distortion compensation unit outputs, as the transmission signal, the predistortion signal acquired from the learning model to the power amplifier, there is a problem that the distortion generated in the transmission signal after power amplification by the power amplifier may not be compensated.

The present disclosure has been made in order to solve the problem as described above, and an object of the present disclosure is to obtain a distortion compensation device capable of compensating distortion generated in a signal after power amplification by a power amplifier even when an operation status of the power amplifier changes.

### Solution to Problem

The distortion compensation device according to the present disclosure includes processing circuitry to acquire an amplification target signal which is a signal to which power amplification by a power amplifier is performed, to acquire an operation status signal indicating an operation status of the power amplifier, to acquire a signal in which distortion is added to the amplification target signal as a predistortion signal for performing compensation of distortion generated in the amplification target signal after the power amplification by the power amplifier on a basis of the amplification target signal and the operation status signal, and to output the predistortion signal to the power amplifier, and to give, when the amplification target signal and the operation status signal are input, the amplification target signal and the operation status signal to a learning model being trained to output a signal to which distortion for compensating distortion generated in the amplification target signal after the power amplification is performed, and acquire the predistortion signal estimated by the learning model without training the learning model, wherein the learning model is implemented by a neural network, and in training, a time-series signal of the amplification target signal, the operation status signal, and the predistortion signal are given to the learning model as training data, the learning model is trained to output the predistortion signal corresponding to the time-series signal of the amplification target signal and the operation status signal which have been input by calculating a weight addition of the time-series signal of the amplification target signal and the operation status signal on a basis of weight coefficients determined by learning of the predistortion signal included in the training data, and the processing circuitry generates, when the amplification target signal is input, a time-series signal of the amplification target signal by delaying the amplification target signal by a predetermined sampling time in order, gives the time-series signal of the amplification target signal being generated and the operation status signal to the learning model, and acquires the predistortion signal estimated by the learning model.

### Advantageous Effects of Invention

According to the present disclosure, even when an operation status of the power amplifier changes, distortion generated in a signal after power amplification by the power amplifier can be compensated.

### BRIEF DESCRIPTION OF DRAWINGS

FIG. 1 is a configuration diagram illustrating a transmission device including a distortion compensation device 2 according to a first embodiment.

FIG. 2 is a hardware configuration diagram illustrating hardware of the distortion compensation device 2 according to the first embodiment.

FIG. 3 is a hardware configuration diagram of a computer in a case where the distortion compensation device 2 is implemented by software, firmware, or the like.

FIG. 4 is a flowchart illustrating a distortion compensation method which is a processing procedure performed by the distortion compensation device 2.

FIG. 5 is an explanatory diagram illustrating configuration examples of a distortion compensation unit 25 and a learning model 24.

FIG. 6 is a configuration diagram illustrating a transmission device including a distortion compensation device 2 according to a second embodiment.

FIG. 7 is a hardware configuration diagram illustrating hardware of the distortion compensation device 2 according to the second embodiment.

FIG. 8 is a configuration diagram illustrating a transmission device including a distortion compensation device 2 according to a third embodiment.

FIG. 9 is a hardware configuration diagram illustrating hardware of the distortion compensation device 2 according to the third embodiment.

FIG. 10 is an explanatory diagram illustrating details of signal value adjustment performed by a signal value adjusting unit 27.

FIG. 11 is a configuration diagram illustrating an example of a transmission device including the distortion compensation device 2.

### DESCRIPTION OF EMBODIMENTS

Hereinafter, in order to describe the present disclosure in more detail, embodiments for carrying out the present disclosure will be described with reference to the attached drawings.

### First Embodiment

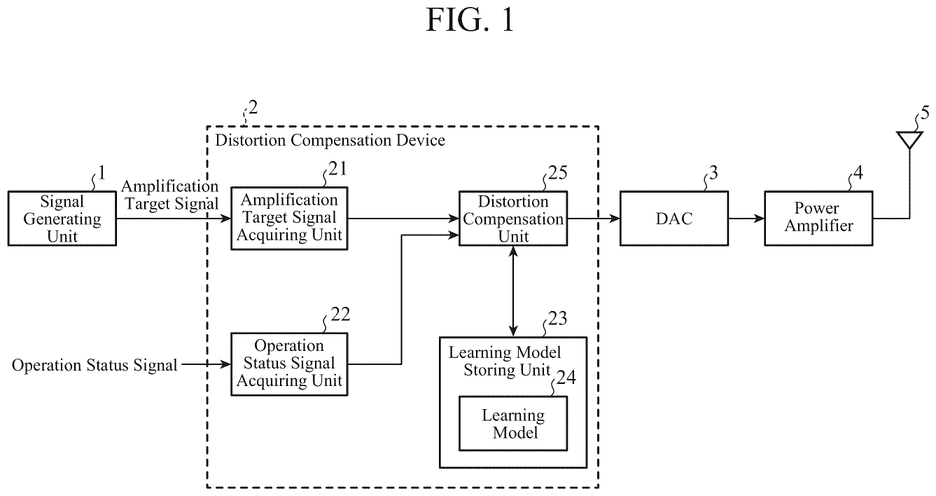

FIG. 1 is a configuration diagram illustrating a transmission device including a distortion compensation device 2 according to a first embodiment.

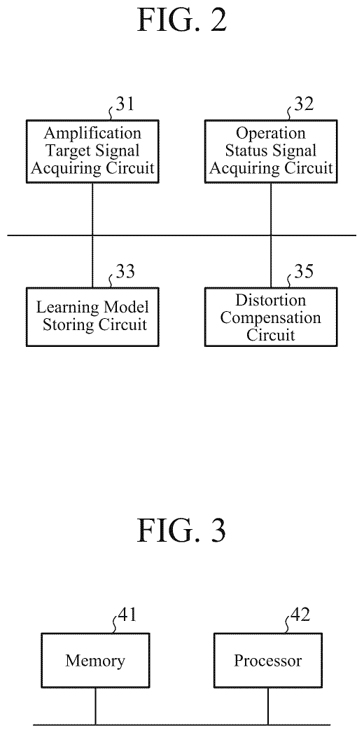

FIG. 2 is a hardware configuration diagram illustrating hardware of the distortion compensation device 2 according to the first embodiment.

The transmission device illustrated in FIG. 1 includes a signal generating unit 1, the distortion compensation device 2, a digital-to-analog converter (hereinafter, referred to as “DAC”) 3, a power amplifier 4, and a transmission antenna 5.

The signal generating unit 1 generates an amplification target signal which is a signal to be power-amplified by the power amplifier 4. The amplification target signal is, for example, a radio frequency (RF) transmission signal.

When a frequency converter that converts an intermediate frequency (IF) baseband signal to an RF transmission signal is disposed at a preceding stage of the power amplifier 4, the amplification target signal may be an IF baseband signal.

The signal generating unit 1 outputs the amplification target signal to the distortion compensation device 2.

The distortion compensation device 2 includes an amplification target signal acquiring unit 21, an operation status signal acquiring unit 22, a learning model storing unit 23, and a distortion compensation unit 25.

The distortion compensation device 2 acquires the amplification target signal from the signal generating unit 1.

The distortion compensation device 2 adds distortion capable of compensating distortion generated in the amplification target signal after power amplification by the power amplifier 4 to the amplification target signal.

The distortion compensation device 2 outputs a predistortion signal, which is an amplification target signal after distortion addition, to the power amplifier 4 via the DAC 3.

The DAC 3 converts the predistortion signal output from the distortion compensation device 2 from a digital signal to an analog signal.

The DAC 3 outputs the analog predistortion signal to the power amplifier 4.

The power amplifier 4 amplifies power of the analog predistortion signal output from the distortion compensation device 2.

The power amplifier 4 outputs, as a transmission signal, the predistortion signal after power amplification to the transmission antenna 5.

The transmission antenna 5 emits a radio wave related to the transmission signal output from the power amplifier 4 into space.

The amplification target signal acquiring unit 21 is implemented by, for example, an amplification target signal acquiring circuit 31 illustrated in FIG. 2.

The amplification target signal acquiring unit 21 acquires the amplification target signal from the signal generating unit 1.

The amplification target signal acquiring unit 21 outputs the amplification target signal to the distortion compensation unit 25.

The operation status signal acquiring unit 22 is implemented by, for example, an operation status signal acquiring circuit 32 illustrated in FIG. 2.

The operation status signal acquiring unit 22 acquires an operation status signal indicating an operation status of the power amplifier 4.

The operation status signal acquiring unit 22 outputs the operation status signal to the distortion compensation unit 25. The operation status signal is a stationary signal having a smaller temporal change in signal value than the amplification target signal.

The operation status signal is, for example, temperature information indicating an ambient temperature of the power amplifier 4, frequency information indicating a carrier frequency of the amplification target signal acquired by the amplification target signal acquiring unit 21, bias voltage information indicating a bias voltage of the power amplifier 4, or backoff information indicating backoff of the power amplifier 4.

When the ambient temperature of the power amplifier 4 changes, distortion generated in the amplification target signal after power amplification by the power amplifier 4 changes. When the carrier frequency of the amplification target signal changes, the distortion generated in the amplification target signal after power amplification by the power amplifier 4 changes. When the bias voltage of the power amplifier 4 changes, the distortion generated in the amplification target signal after power amplification by the power amplifier 4 changes. When the backoff of the power amplifier 4 changes, the distortion generated in the amplification target signal after power amplification by the power amplifier 4 changes.

The learning model storing unit 23 is implemented by, for example, a learning model storing circuit 33 illustrated in FIG. 2.

The learning model storing unit 23 stores a learning model 24.

The distortion compensation device 2 illustrated in FIG. 1 includes the learning model storing unit 23. However, this is merely an example, and the learning model storing unit 23 may be disposed outside the distortion compensation device 2.

The learning model 24 is implemented by, for example, a neural network.

To the learning model 24, at the time of training, the amplification target signal acquired by the amplification target signal acquiring unit 21, the operation status signal acquired by the operation status signal acquiring unit 22, and the predistortion signal capable of compensating distortion generated in the amplification target signal after power amplification by the power amplifier 4 are given as training data.

The learning model 24 is a trained model in which the predistortion signal included in the training data has been learned.

The distortion compensation unit 25 is implemented by, for example, a distortion compensation circuit 35 illustrated in FIG. 2.

The distortion compensation unit 25 estimates a signal in which distortion is added to the amplification target signal acquired by the amplification target signal acquiring unit 21 as the predistortion signal for compensating distortion generated in the amplification target signal after power amplification by the power amplifier 4 on the basis of the amplification target signal acquired by the amplification target signal acquiring unit 21 and the operation status signal acquired by the operation status signal acquiring unit 22.

Specifically, the distortion compensation unit 25 gives the amplification target signal acquired by the amplification target signal acquiring unit 21 and the operation status signal acquired by the operation status signal acquiring unit 22 to the learning model 24.

The distortion compensation unit 25 acquires, from the learning model 24, a signal in which distortion is added to the amplification target signal acquired by the amplification target signal acquiring unit 21 as the predistortion signal for compensating distortion generated in the amplification target signal after power amplification by the power amplifier 4.

The distortion compensation unit 25 outputs the predistortion signal to the power amplifier 4 via the DAC 3.

In the distortion compensation device 2 illustrated in FIG. 1, the distortion compensation unit 25 estimates the predistortion signal for compensating distortion generated in the amplification target signal after power amplification by the power amplifier 4 using the learning model 24. However, this is merely an example, and the distortion compensation unit 25 may estimate the predistortion signal for compensating distortion generated in the amplification target signal after power amplification by the power amplifier 4 using, for example, a rule base. In the rule base, a rule for determining predistortion signals corresponding to the amplification target signal acquired by the amplification target signal acquiring unit 21 and the operation status signal acquired by the operation status signal acquiring unit 22 is described.

In FIG. 1, it is assumed that each of the amplification target signal acquiring unit 21, the operation status signal acquiring unit 22, the learning model storing unit 23, and the distortion compensation unit 25, which are constituent elements of the distortion compensation device 2, is implemented by dedicated hardware as illustrated in FIG. 2. That is, it is assumed that the distortion compensation device 2 is implemented by the amplification target signal acquiring circuit 31, the operation status signal acquiring circuit 32, the learning model storing circuit 33, and the distortion compensation circuit 35.

To the learning model storing circuit 33, a nonvolatile or volatile semiconductor memory such as a random access memory (RAM), a read only memory (ROM), a flash memory, an erasable programmable read only memory (EPROM), or an electrically erasable programmable read only memory (EEPROM), a magnetic disk, a flexible disk, an optical disc, a compact disc, a mini disc, or a digital versatile disc (DVD) corresponds.

To each of the amplification target signal acquiring circuit 31, the operation status signal acquiring circuit 32, and the distortion compensation circuit 35, a single circuit, a composite circuit, a programmed processor, a parallel programmed processor, an application specific integrated circuit (ASIC), a field-programmable gate array (FPGA), or a combination thereof corresponds.

The constituent elements of the distortion compensation device 2 are not limited to those implemented by dedicated hardware, and the distortion compensation device 2 may be implemented by software, firmware, or a combination of software and firmware.

Software or firmware is stored as a program in a memory of a computer. The computer means hardware for executing a program. To the computer, for example, a central processing unit (CPU), a central processing device, a processing device, an arithmetic device, a microprocessor, a microcomputer, a processor, or a digital signal processor (DSP) corresponds.

FIG. 3 is a hardware configuration diagram of a computer in a case where the distortion compensation device 2 is implemented by software, firmware, or the like.

In a case where the distortion compensation device 2 is implemented by software, firmware, or the like, the learning model storing unit 23 is constituted on a memory 41 of the computer. A program for causing the computer to execute a processing procedure performed in each of the amplification target signal acquiring unit 21, the operation status signal acquiring unit 22, and the distortion compensation unit 25 is stored in the memory 41. A processor 42 of the computer executes the program stored in the memory 41.

FIG. 2 illustrates an example in which each of the constituent elements of the distortion compensation device 2 is implemented by dedicated hardware, and FIG. 3 illustrates an example in which the distortion compensation device 2 is implemented by software, firmware, or the like. However, this is merely an example, and some of the constituent elements of the distortion compensation device 2 may be implemented by dedicated hardware, and the remaining constituent elements may be implemented by software, firmware, or the like.

Next, an operation of the distortion compensation device 2 illustrated in FIG. 1 will be described.

The signal generating unit 1 generates an amplification target signal S which is a signal to be power-amplified. The amplification target signal S includes, for example, an I signal which is an in-phase signal and a Q signal which is a quadrature signal.

Hereinafter, the I signal at time (t) generated by the signal generating unit 1 is represented by I_{IN}(t), and the Q signal at time (t) is represented by Q_{IN}(t).

The signal generating unit 1 outputs the amplification target signal S to the distortion compensation device 2.

In the distortion compensation device 2 illustrated in FIG. 1, the signal generating unit 1 generates the amplification target signal S including the I signal and the Q signal. However, the amplification target signal S may be any signal that can be amplified by the power amplifier 4, and may be a signal not including the I signal and the Q signal.

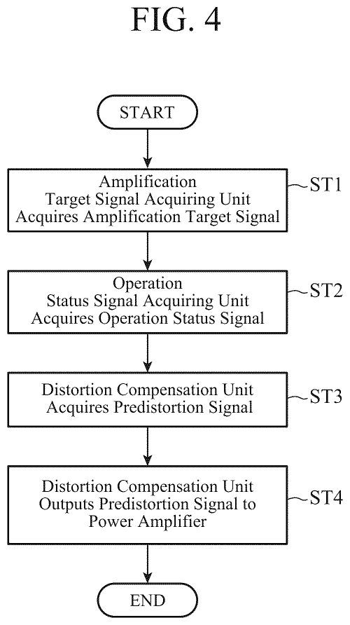

FIG. 4 is a flowchart illustrating a distortion compensation method which is a processing procedure performed by the distortion compensation device 2.

The amplification target signal acquiring unit 21 of the distortion compensation device 2 acquires the amplification target signal S from the signal generating unit 1 (step ST1 in FIG. 4).

The amplification target signal acquiring unit 21 outputs the amplification target signal S to the distortion compensation unit 25.

The operation status signal acquiring unit 22 acquires an operation status signal OC indicating an operation status of the power amplifier 4 (step ST2 in FIG. 4).

The operation status signal acquiring unit 22 outputs the operation status signal OC to the distortion compensation unit 25.

When the operation status signal OC is, for example, temperature information indicating an ambient temperature of the power amplifier 4, the operation status signal acquiring unit 22 acquires the operation status signal OC from a temperature sensor that observes the ambient temperature of the power amplifier 4.

When the operation status signal OC is, for example, frequency information indicating a carrier frequency of the amplification target signal, the operation status signal acquiring unit 22 acquires the operation status signal OC from a control device that controls the transmission device.

In the distortion compensation device 2 illustrated in FIG. 1, the operation status signal acquiring unit 22 acquires one operation status signal OC and outputs the one operation status signal OC to the distortion compensation unit 25. However, this is merely an example, and the operation status signal acquiring unit 22 may obtain two or more operation status signals OC and output the two or more operation status signals OC to the distortion compensation unit 25.

The distortion compensation unit 25 acquires the amplification target signal S from the amplification target signal acquiring unit 21, and acquires the operation status signal OC from the operation status signal acquiring unit 22. In the distortion compensation device 2 illustrated in FIG. 1, the amplification target signal S includes I_{IN}(t) and Q_{IN}(t).

The distortion compensation unit 25 gives each of I_{IN}(t), Q_{IN}(t), and the operation status signal OC to the learning model 24.

The distortion compensation unit 25 acquires, from the learning model 24, a predistortion signal for compensating distortion generated in an amplification target signal S′ after power amplification by the power amplifier 4 (step ST3 in FIG. 4).

The predistortion signal is a signal in which distortion is added to the amplification target signal S in order to eliminate distortion generated in the amplification target signal S′ after power amplification by the power amplifier 4. Generally, the distortion added to the amplification target signal S is distortion having a characteristic opposite to the distortion generated in the amplification target signal S′ after power amplification by the power amplifier 4.

The predistortion signal output from the learning model 24 includes I_{OUT}(t) and Q_{OUT}(t).

The distortion compensation unit 25 outputs the predistortion signal including I_{OUT}(t) and Q_{OUT}(t) to the power amplifier 4 via the DAC 3 (step ST4 in FIG. 4).

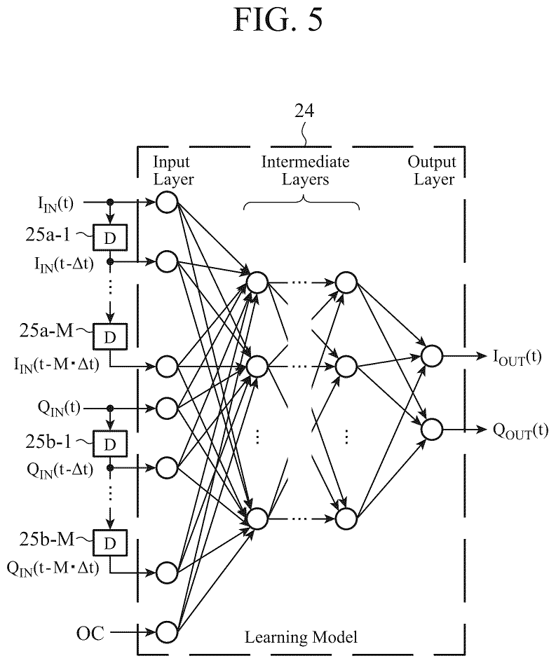

FIG. 5 is an explanatory diagram illustrating configuration examples of the distortion compensation unit 25 and the learning model 24.

In FIG. 5, the distortion compensation unit 25 includes M first delayers 25a-m and M second delayers 25b-m. m=1, . . . , M, and M is an integer equal to or more than 2. In FIG. 5, each of the first delayers 25a-m and the second delayers 25b-m is denoted as “D”. Here, it is assumed that a sampling interval of the distortion compensation unit 25 is Δt.

I_{IN}(t) at time (t) is given to any one of a plurality of input layers of the learning model 24. A first delayer 25a-1 delays I_{IN}(t) at time (t) by one sampling time Δt.

I_{IN}(t−Δt), which is an output signal of the first delayer 25a-1, is obtained by delaying a signal given before one sampling time by Δt, and is given to any one of the plurality of input layers. In addition, I_{IN}(t−Δt) is given to a first delayer 25a-2.

A first delayer 25a-m (m=2, . . . , M) delays I_{IN}(t-(m−1)·Δt), which is an output signal of a first delayer 25a-(m−1), by one sampling time Δt.

I_{IN}(t−m·Δt), which is an output signal of the first delayer 25a-m, is obtained by delaying a signal given before one sampling time by Δt, and is given to any one of the plurality of input layers. In addition, I_{IN}(t−m·Δt) is given to a first delayer 25a-(m+1). Note that, when m=M, I_{IN}(t−m·Δt) is not given to the first delayer 25a-(m+1).

Q_{IN}(t) at time (t) is given to any one of the plurality of input layers of the learning model 24. A second delayer 25b-1 delays Q_{IN}(t) at time (t) by one sampling time Δt.

Q_{IN}(t−Δt), which is an output signal of the second delayer 25b-1, is obtained by delaying a signal given before one sampling time by Δt, and is given to any one of the plurality of input layers. In addition, Q_{IN}(t−Δt) is given to a second delayer 25b-2.

A second delayer 25b-m (m=2, . . . , M) delays Q_{IN}(t-(m−1)·Δt), which is an output signal of a second delayer 25b-(m−1), by one sampling time Δt.

Q_{IN}(t−m·Δt), which is an output signal of the second delayer 25b-m, is obtained by delaying a signal given before one sampling time by Δt, and is given to any one of the plurality of input layers. In addition, Q_{IN}(t−m·Δt) is given to a second delayer 25b-(m+1). Note that, when m=M, Q_{IN}(t−m·Δt) is not given to the second delayer 25b-(m+1).

Among the plurality of input layers of the learning model 24, the operation status signal OC is given to an input layer other than an input layer to which I_{IN}(t), I_{IN}(t−m·Δt), Q_{IN}(t), or Q_{IN}(t−m·Δt) is given. As the operation status signal OC, for example, an operation status signal OC indicating temperature information, an operation status signal OC indicating frequency information, an operation status signal OC indicating bias information, or an operation status signal OC indicating backoff information is given to an input layer.

A signal given to an input layer of the learning model 24 is propagated to each of a plurality of intermediate layers in the learning model 24. Weight addition of the plurality of signals propagated to each of the intermediate layers is performed on the basis of a weighting factor determined by learning of the predistortion signal included in the training data.

The signal subjected to the weight addition in each of the intermediate layers is propagated to each of two output layers. Weight addition of the plurality of signals propagated to each of the output layers is performed on the basis of a weighting factor determined by learning of the predistortion signal included in the training data.

The signal subjected to weight addition in each of the output layers is an amplification target signal after distortion addition. The amplification target signal after distortion addition is a predistortion signal including I_{OUT}(t) and Q_{OUT}(t).

To an input layer of the learning model 24 illustrated in FIG. 5, not only I_{IN} (t) and Q_{IN}(t) at a current time t but also I_{IN}(t−m·Δt) and Q_{IN}(t−m·Δt) (m=1, . . . , M) are given. Therefore, learning of the predistortion signal is performed in consideration of a change in a time-series signal including a current signal and a past signal. Therefore, the distortion compensation unit 25 can acquire the predistortion signal corresponding to a temporal change of the amplification target signal S from the learning model 24.

Note that the input layer of the learning model 24 is not limited to one to which a time-series signal is given, and may be one to which only I_{IN}(t) and Q_{IN}(t) are given.

The DAC 3 acquires the predistortion signal, which is an amplification target signal after distortion addition, from the distortion compensation device 2.

The DAC 3 converts the predistortion signal output from a digital signal to an analog signal.

The DAC 3 outputs the analog predistortion signal to the power amplifier 4.

The power amplifier 4 acquires the analog predistortion signal from the distortion compensation device 2.

The power amplifier 4 amplifies power of the analog predistortion signal, and outputs the predistortion signal after power amplification to the transmission antenna 5.

The predistortion signal is an amplification target signal to which distortion is added in order to compensate distortion generated in a signal after power amplification by the power amplifier 4. Therefore, the transmission signal, which is a signal after power amplification by the power amplifier 4, is a signal in which little distortion is generated.

The power amplifier 4 outputs the transmission signal after power amplification to the transmission antenna 5.

The transmission antenna 5 emits a radio wave related to the transmission signal output from the power amplifier 4 into space.

In the first embodiment described above, the distortion compensation device 2 includes the amplification target signal acquiring unit 21 that acquires an amplification target signal which is a signal to be power-amplified by the power amplifier 4 and the operation status signal acquiring unit 22 that acquires an operation status signal indicating an operation status of the power amplifier 4. In addition, the distortion compensation device 2 includes the distortion compensation unit 25 that estimates a signal in which distortion is added to the amplification target signal acquired by the amplification target signal acquiring unit 21 as a predistortion signal for compensating distortion generated in the amplification target signal after power amplification by the power amplifier 4 on the basis of the amplification target signal acquired by the amplification target signal acquiring unit 21 and the operation status signal acquired by the operation status signal acquiring unit 22, and outputs the predistortion signal to the power amplifier 4. Therefore, even when an operation status of the power amplifier 4 changes, the distortion compensation device 2 can compensate distortion generated in a signal after power amplification by the power amplifier 4.

### Second Embodiment

In a second embodiment, a distortion compensation device 2 including a learning processing unit 26 that gives training data to a learning model 24 and causes the learning model 24 to learn a predistortion signal included in the training data will be described.

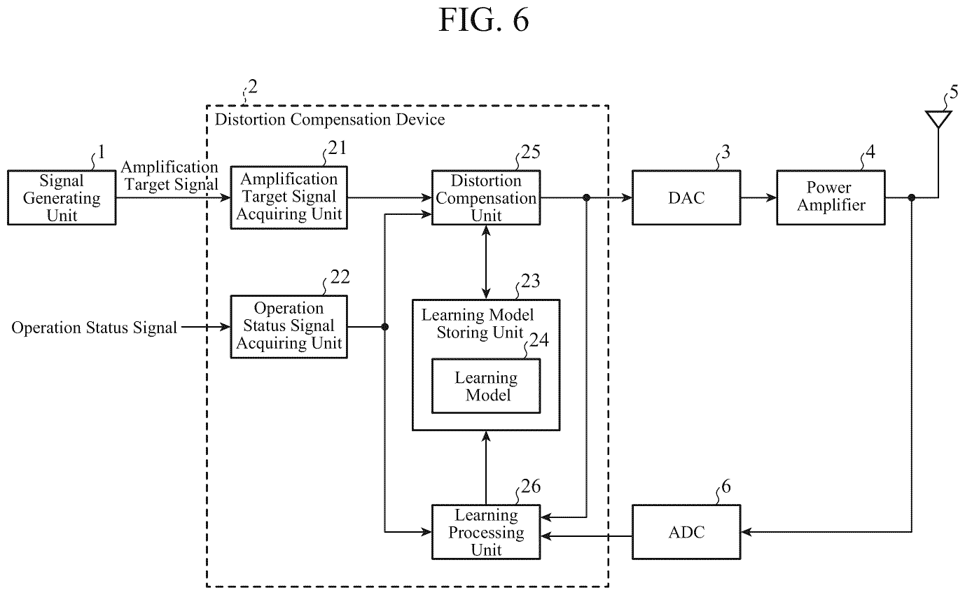

FIG. 6 is a configuration diagram illustrating a transmission device including the distortion compensation device 2 according to the second embodiment. In FIG. 6, the same reference numerals as in FIG. 1 indicate the same or corresponding parts, and therefore description thereof is omitted.

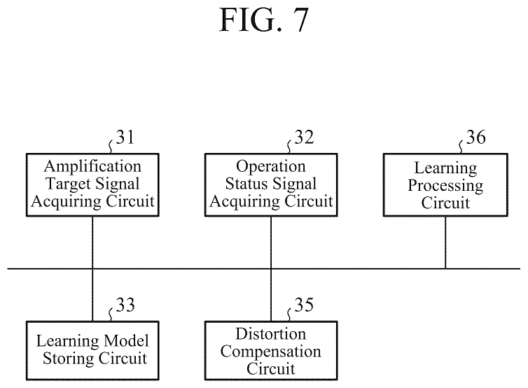

FIG. 7 is a hardware configuration diagram illustrating hardware of the distortion compensation device 2 according to the second embodiment. In FIG. 7, the same reference numerals as in FIG. 2 indicate the same or corresponding parts, and therefore description thereof is omitted.

The transmission device illustrated in FIG. 6 includes a signal generating unit 1, the distortion compensation device 2, a DAC 3, a power amplifier 4, a transmission antenna 5, and an analog-to-digital converter (hereinafter, referred to as “ADC”) 6.

The ADC 6 converts an amplification target signal after power amplification by the power amplifier 4 from an analog signal to a digital signal.

The ADC 6 outputs the digital amplification target signal to the distortion compensation device 2.

The distortion compensation device 2 illustrated in FIG. 6 includes an amplification target signal acquiring unit 21, an operation status signal acquiring unit 22, a learning model storing unit 23, a distortion compensation unit 25, and a learning processing unit 26.

The learning processing unit 26 is implemented by, for example, a learning processing circuit 36 illustrated in FIG. 7.

The learning processing unit 26 acquires training data to be given to the learning model 24.

The training data acquired by the learning processing unit 26 includes the digital amplification target signal output from the ADC 6, an operation status signal acquired by the operation status signal acquiring unit 22, and a predistortion signal output from the distortion compensation unit 25. The digital amplification target signal output from the ADC 6 corresponds to an amplification target signal after power amplification by the power amplifier 4. The predistortion signal included in the training data is a signal used as a teacher signal.

The learning processing unit 26 gives the training data to the learning model 24 and causes the learning model 24 to learn the predistortion signal included in the training data.

In FIG. 6, it is assumed that each of the amplification target signal acquiring unit 21, the operation status signal acquiring unit 22, the learning model storing unit 23, the distortion compensation unit 25, and the learning processing unit 26, which are constituent elements of the distortion compensation device 2, is implemented by dedicated hardware as illustrated in FIG. 7. That is, it is assumed that the distortion compensation device 2 is implemented by the amplification target signal acquiring circuit 31, the operation status signal acquiring circuit 32, the learning model storing circuit 33, the distortion compensation circuit 35, and the learning processing circuit 36.

To each of the amplification target signal acquiring circuit 31, the operation status signal acquiring circuit 32, the distortion compensation circuit 35, and the learning processing circuit 36, for example, a single circuit, a composite circuit, a programmed processor, a parallel programmed processor, an ASIC, a FPGA, or a combination thereof corresponds.

The constituent elements of the distortion compensation device 2 are not limited to those implemented by dedicated hardware, and the distortion compensation device 2 may be implemented by software, firmware, or a combination of software and firmware.

In a case where the distortion compensation device 2 is implemented by software, firmware, or the like, the learning model storing unit 23 is constituted on a memory 41 illustrated in FIG. 3. A program for causing a computer to execute a processing procedure performed in each of the amplification target signal acquiring unit 21, the operation status signal acquiring unit 22, the distortion compensation unit 25, and the learning processing unit 26 is stored in the memory 41. A processor 42 illustrated in FIG. 3 executes the program stored in the memory 41.

FIG. 7 illustrates an example in which each of the constituent elements of the distortion compensation device 2 is implemented by dedicated hardware, and FIG. 3 illustrates an example in which the distortion compensation device 2 is implemented by software, firmware, or the like. However, this is merely an example, and some of the constituent elements of the distortion compensation device 2 may be implemented by dedicated hardware, and the remaining constituent elements may be implemented by software, firmware, or the like.

Next, an operation of the distortion compensation device 2 illustrated in FIG. 6 will be described. Components other than the learning processing unit 26 are similar to those of the distortion compensation device 2 illustrated in FIG. 1, and therefore an operation of the learning processing unit 26 will be mainly described here.

Most of power of the amplification target signal after power amplification by the power amplifier 4 is output to the transmission antenna 5, and a part of the power of the amplification target signal is output to the ADC 6.

The ADC 6 converts an amplification target signal after power amplification by the power amplifier 4 from an analog signal to a digital signal.

The ADC 6 outputs the digital amplification target signal to the distortion compensation device 2.

The learning processing unit 26 acquires training data to be given to the learning model 24.

That is, the learning processing unit 26 acquires, as the training data, the digital amplification target signal output from the ADC 6, the operation status signal OC output from the operation status signal acquiring unit 22, and the predistortion signal output from the distortion compensation unit 25.

The learning processing unit 26 gives the training data to the learning model 24 and causes the learning model 24 to learn the predistortion signal included in the training data.

When the amplification target signal S acquired by the amplification target signal acquiring unit 21 and the operation status signal OC acquired by the operation status signal acquiring unit 22 are given to the trained learning model 24, the trained learning model 24 outputs a predistortion signal corresponding to each of the amplification target signal S and the operation status signal OC.

The distortion compensation unit 25 acquires the amplification target signal S from the amplification target signal acquiring unit 21, and acquires the operation status signal OC from the operation status signal acquiring unit 22. The amplification target signal S includes I_{IN}(t) and Q_{IN}(t).

The distortion compensation unit 25 gives each of I_{IN}(t), Q_{IN}(t), and the operation status signal OC to the trained learning model 24.

The distortion compensation unit 25 acquires, from the learning model 24, a predistortion signal for compensating distortion generated in an amplification target signal S′ after power amplification by the power amplifier 4.

In the second embodiment described above, the distortion compensation device 2 includes the learning processing unit 26 that acquires, as training data, an amplification target signal after power amplification by the power amplifier 4, an operation status signal acquired by the operation status signal acquiring unit 22, and a predistortion signal output from the distortion compensation unit 25, gives the training data to the learning model 24, and causes the learning model 24 to learn the predistortion signal. Therefore, even when an operation status of the power amplifier 4 changes, the distortion compensation device 2 can compensate distortion generated in a signal after power amplification by the power amplifier 4, and can cause the learning model 24 to learn the predistortion signal.

### Third Embodiment

In a third embodiment, a distortion compensation device 2 including a signal value adjusting unit 27 that adjusts a signal value of an operation status signal OC will be described.

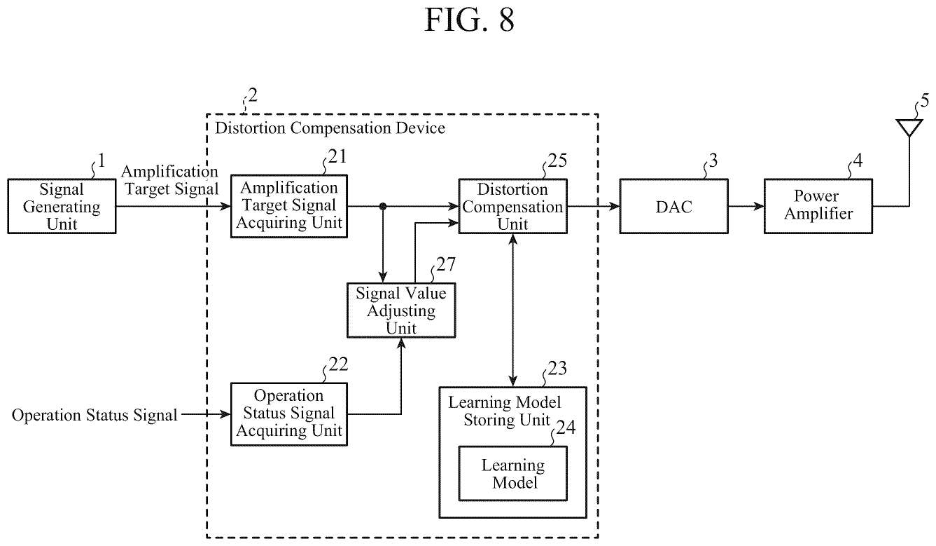

FIG. 8 is a configuration diagram illustrating a transmission device including the distortion compensation device 2 according to the third embodiment. In FIG. 8, the same reference numerals as in FIGS. 1 and 6 indicate the same or corresponding parts, and therefore description thereof is omitted.

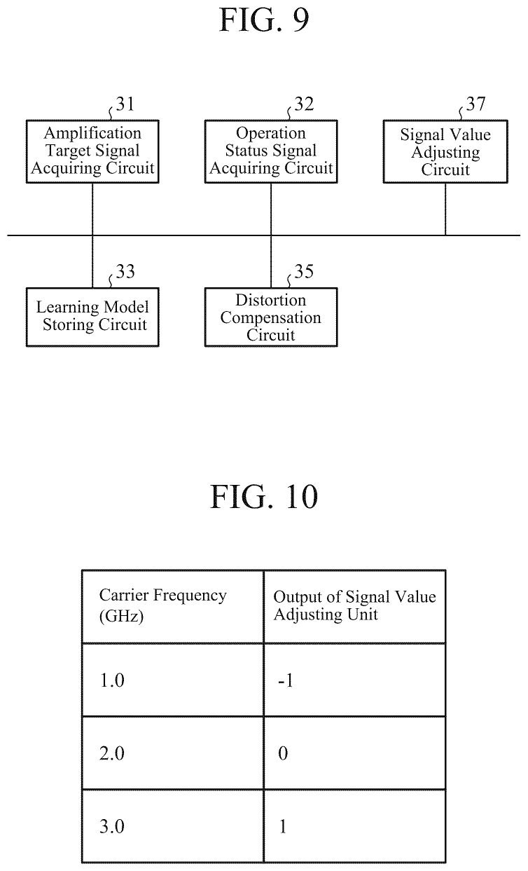

FIG. 9 is a hardware configuration diagram illustrating hardware of the distortion compensation device 2 according to the third embodiment. In FIG. 9, the same reference numerals as in FIGS. 2 and 7 indicate the same or corresponding parts, and therefore description thereof is omitted.

The signal value adjusting unit 27 is implemented by, for example, a signal value adjusting circuit 37 illustrated in FIG. 9.

The signal value adjusting unit 27 adjusts a signal value of an operation status signal OC acquired by an operation status signal acquiring unit 22 in such a manner that a signal change width of the operation status signal OC is equal to a signal change width of an amplification target signal S acquired by an amplification target signal acquiring unit 21.

The signal value adjusting unit 27 outputs an operation status signal OC′ after signal value adjustment to a distortion compensation unit 25.

In the distortion compensation device 2 illustrated in FIG. 8, the signal value adjusting unit 27 is applied to the distortion compensation device 2 illustrated in FIG. 1. However, this is merely an example, and the signal value adjusting unit 27 may be applied to the distortion compensation device 2 illustrated in FIG. 6.

In FIG. 8, it is assumed that each of the amplification target signal acquiring unit 21, the operation status signal acquiring unit 22, a learning model storing unit 23, the signal value adjusting unit 27, and the distortion compensation unit 25, which are constituent elements of the distortion compensation device 2, is implemented by dedicated hardware as illustrated in FIG. 9. That is, it is assumed that the distortion compensation device 2 is implemented by an amplification target signal acquiring circuit 31, an operation status signal acquiring circuit 32, a learning model storing circuit 33, the signal value adjusting circuit 37, and a distortion compensation circuit 35.

To each of the amplification target signal acquiring circuit 31, the operation status signal acquiring circuit 32, the signal value adjusting circuit 37, and the distortion compensation circuit 35, for example, a single circuit, a composite circuit, a programmed processor, a parallel programmed processor, an ASIC, an FPGA, or a combination thereof corresponds.

The constituent elements of the distortion compensation device 2 are not limited to those implemented by dedicated hardware, and the distortion compensation device 2 may be implemented by software, firmware, or a combination of software and firmware.

In a case where the distortion compensation device 2 is implemented by software, firmware, or the like, the learning model storing unit 23 is constituted on a memory 41 illustrated in FIG. 3. A program for causing a computer to execute a processing procedure performed in each of the amplification target signal acquiring unit 21, the operation status signal acquiring unit 22, the signal value adjusting unit 27, and the distortion compensation unit 25 is stored in the memory 41. A processor 42 illustrated in FIG. 3 executes the program stored in the memory 41.

FIG. 9 illustrates an example in which each of the constituent elements of the distortion compensation device 2 is implemented by dedicated hardware, and FIG. 3 illustrates an example in which the distortion compensation device 2 is implemented by software, firmware, or the like. However, this is merely an example, and some of the constituent elements of the distortion compensation device 2 may be implemented by dedicated hardware, and the remaining constituent elements may be implemented by software, firmware, or the like.

Next, an operation of the distortion compensation device 2 illustrated in FIG. 8 will be described. Components other than the signal value adjusting unit 27 are similar to those of the distortion compensation device 2 illustrated in FIG. 1, and therefore an operation of the signal value adjusting unit 27 will be mainly described here.

The signal value adjusting unit 27 acquires the amplification target signal S from the amplification target signal acquiring unit 21, and acquires the operation status signal OC from the operation status signal acquiring unit 22.

The signal value adjusting unit 27 adjusts a signal value of the operation status signal OC in such a manner that a signal change width of the operation status signal OC is equal to a signal change width of the amplification target signal S.

For example, in a case where the operation status signal OC is frequency information indicating a carrier frequency of the amplification target signal S and the signal change width of the carrier frequency is 1.0 [GHz] to 3.0 [GHz] as illustrated in FIG. 10, when an upper limit value of the signal value of the amplification target signal S is “1” and a lower limit value of the signal value of the amplification target signal S is “−1”, the signal value adjusting unit 27 adjusts the signal value of the operation status signal OC as follows.

FIG. 10 is an explanatory diagram illustrating details of signal value adjustment performed by the signal value adjusting unit 27.

When the signal value of the operation status signal OC acquired from the operation status signal acquiring unit 22 is, for example, “3.0” as the upper limit value, the signal value adjusting unit 27 adjusts the signal value of the operation status signal OC to “1” in such a manner that the signal value is equal to the upper limit value “1” of the signal value of the amplification target signal S.

When the signal value of the operation status signal OC acquired from the operation status signal acquiring unit 22 is, for example, “1.0” as the lower limit value, the signal value adjusting unit 27 adjusts the signal value of the operation status signal OC to “−1” in such a manner that the signal value is equal to the lower limit value “−1” of the signal value of the amplification target signal S.

When the signal value of the operation status signal OC acquired from the operation status signal acquiring unit 22 is, for example, “2.0” as a median value, the signal value adjusting unit 27 adjusts the signal value of the operation status signal OC to “0” in such a manner that the signal value is equal to the median value “0” of the signal value of the amplification target signal S.

The signal value adjusting unit 27 outputs the operation status signal OC′ after signal value adjustment to the distortion compensation unit 25.

Here, an example is illustrated in which the operation status signal OC is frequency information indicating a carrier frequency of the amplification target signal. However, this is merely an example, and the operation status signal OC may be temperature information indicating an ambient temperature of the power amplifier 4, bias voltage information indicating a bias voltage of the power amplifier 4, or backoff information indicating backoff of the power amplifier 4. Also in this case, the signal value adjusting unit 27 adjusts the signal value of the operation status signal OC similarly to the frequency information indicating a carrier frequency.

The distortion compensation unit 25 acquires the amplification target signal S from the amplification target signal acquiring unit 21, and acquires the operation status signal OC′ after signal value adjustment from the signal value adjusting unit 27. The amplification target signal includes I_{IN}(t) and Q_{IN}(t).

The distortion compensation unit 25 gives each of I_{IN}(t), Q_{IN}(t), and the operation status signal OC′ to the trained learning model 24.

In the learning model 24, at the time of training, an upper limit of a weight for the amplification target signal S in a neural network is the same as an upper limit of a weight for the operation status signal OC′ in the neural network by the operation status signal OC′ after signal value adjustment being given to the learning model 24. Therefore, biased learning in which the amplification target signal S is emphasized more than the operation status signal OC is prevented. In addition, biased learning in which the operation status signal OC is emphasized more than the amplification target signal S is prevented. That is, the amplification target signal S and the operation status signal OC′ are learned with a similar weight. As a result, predistortion signal learning accuracy by the learning model 24 is improved.

In addition, even when the distortion compensation unit 25 acquires the predistortion signal from the learning model 24, the distortion compensation unit 25 can acquire a predistortion signal with high distortion compensation accuracy.

In the third embodiment described above, the distortion compensation device 2 illustrated in FIG. 8 includes the signal value adjusting unit 27 that adjusts a signal value of an operation status signal acquired by the operation status signal acquiring unit 22 in such a manner that a signal change width of the operation status signal is equal to a signal change width of an amplification target signal acquired by the amplification target signal acquiring unit 21, and outputs the operation status signal after signal value adjustment to the distortion compensation unit 25. Therefore, even when an operation status of the power amplifier 4 changes, the distortion compensation device 2 illustrated in FIG. 8 can compensate distortion generated in a signal after power amplification by the power amplifier 4, and can compensate distortion with higher accuracy than the distortion compensation device 2 illustrated in FIG. 1.

Each of the transmission device illustrated in FIG. 1 and the transmission device illustrated in FIG. 8 includes the signal generating unit 1, the distortion compensation device 2, the DAC 3, the power amplifier 4, and the transmission antenna 5. The transmission device illustrated in FIG. 6 includes the signal generating unit 1, the distortion compensation device 2, the DAC 3, the power amplifier 4, the transmission antenna 5, and the ADC 6.

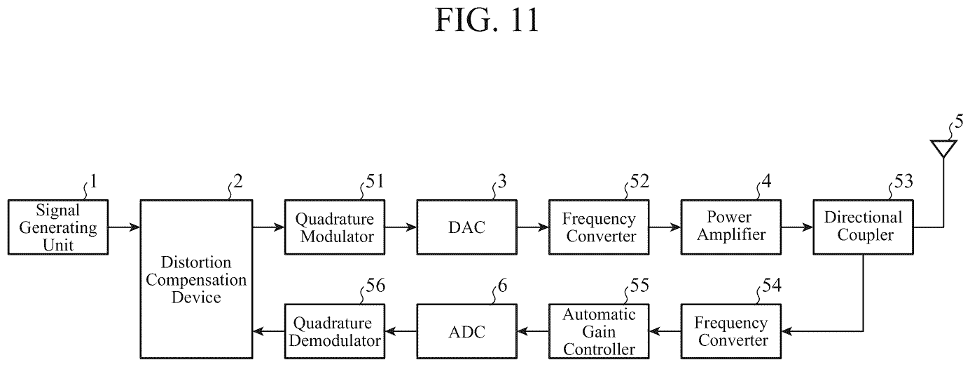

However, these are merely examples, and the transmission device may include the signal generating unit 1, the distortion compensation device 2, a quadrature modulator 51, the DAC 3, a frequency converter 52, the power amplifier 4, a directional coupler 53, the transmission antenna 5, a frequency converter 54, an automatic gain controller 55, the ADC 6, and a quadrature demodulator 56 as illustrated in FIG. 11.

FIG. 11 is a configuration diagram illustrating an example of a transmission device including the distortion compensation device 2.

In FIG. 11, for convenience of description, it is assumed that the signal generating unit 1 generates an IF baseband signal as an amplification target signal.

The quadrature modulator 51 performs quadrature modulation on a baseband signal after distortion addition, which is a predistortion signal output from the distortion compensation device 2, using a carrier signal.

The quadrature modulator 51 outputs a transmission signal, which is a baseband signal after quadrature modulation, to the DAC 3.

The frequency converter 52 converts a frequency of the analog transmission signal output from the DAC 3 to, for example, RF.

The frequency converter 52 outputs the transmission signal having a frequency of RF to the power amplifier 4.

The directional coupler 53 divides the transmission signal after power amplification by the power amplifier 4 into two.

The directional coupler 53 outputs one of the two transmission signals after division to the transmission antenna 5 and outputs the other transmission signal to the frequency converter 54.

The frequency converter 54 converts a frequency of the transmission signal output from the directional coupler 53 to, for example, IF.

The frequency converter 54 outputs the transmission signal having a frequency of IF to the automatic gain controller 55.

The automatic gain controller 55 controls a gain of the transmission signal output from the frequency converter 54.

The automatic gain controller 55 outputs the transmission signal after gain control to the ADC 6.

The quadrature demodulator 56 performs quadrature demodulation on the digital transmission signal output from the ADC 6 using a carrier signal.

The quadrature demodulator 56 outputs a baseband signal, which is the transmission signal after quadrature demodulation, to the distortion compensation device 2.

Note that the present disclosure can freely combine the embodiments to each other, modify any constituent element in each of the embodiments, or omit any constituent element in each of the embodiments.

### INDUSTRIAL APPLICABILITY

The present disclosure is suitable for a distortion compensation device, a distortion compensation method, and a transmission device.

### REFERENCE SIGNS LIST

1: signal generating unit, 2: distortion compensation device, 3: DAC, 4: power amplifier, 5: transmission antenna, 6: ADC, 21: amplification target signal acquiring unit, 22: operation status signal acquiring unit, 23: learning model storing unit, 24: learning model, 25: distortion compensation unit, 25a-1 to 25a-M: first delayer, 25b-1 to 25b-M: second delayer, 26: learning processing unit, 27: signal value adjusting unit, 31: amplification target signal acquiring circuit, 32: operation status signal acquiring circuit, 33: learning model storing circuit, 35: distortion compensation circuit, 36: learning processing circuit, 37: signal value adjusting circuit, 41: memory, 42: processor, 51: quadrature modulator, 52: frequency converter, 53: directional coupler, 54: frequency converter, 55: automatic gain controller, 56: quadrature demodulator

1. A distortion compensation device comprising processing circuitry
to acquire an amplification target signal which is a signal to which power amplification by a power amplifier is performed,
to acquire an operation status signal indicating an operation status of the power amplifier,
to acquire a signal in which distortion is added to the amplification target signal as a predistortion signal for performing compensation of distortion generated in the amplification target signal after the power amplification by the power amplifier on a basis of the amplification target signal and the operation status signal, and to output the predistortion signal to the power amplifier, and
to give, when the amplification target signal and the operation status signal are input, the amplification target signal and the operation status signal to a learning model being trained to output a signal to which distortion for compensating distortion generated in the amplification target signal after the power amplification is performed, and acquire the predistortion signal estimated by the learning model without training the learning model,
wherein the learning model is implemented by a neural network, and in training, a time-series signal of the amplification target signal, the operation status signal, and the predistortion signal are given to the learning model as training data,
the learning model is trained to output the predistortion signal corresponding to the time-series signal of the amplification target signal and the operation status signal which have been input by calculating a weight addition of the time-series signal of the amplification target signal and the operation status signal on a basis of weight coefficients determined by learning of the predistortion signal included in the training data, and
the processing circuitry generates, when the amplification target signal is input, a time-series signal of the amplification target signal by delaying the amplification target signal by a predetermined sampling time in order, gives the time-series signal of the amplification target signal being generated and the operation status signal to the learning model, and acquires the predistortion signal estimated by the learning model

2. The distortion compensation device according to claim 1, wherein
the learning model is trained using at least two of temperature information, frequency information, bias information, and backoff information.

3. The distortion compensation device according to claim 2, the processing circuitry is further configured to acquire, as training data, the amplification target signal after the power amplification by the power amplifier, the operation status signal, and the predistortion signal, to give the training data to the learning model, and to cause the learning model to learn the predistortion signal.

4. The distortion compensation device according to claim 1, wherein the processing circuitry is further configured to perform adjustment of a signal value of the operation status signal in such a manner that a signal change width of the operation status signal is equal to a signal change width of the amplification target signal, and to generate the operation status signal after the adjustment for the compensation.

5. The distortion compensation device according to claim 1, wherein
the processing circuitry is further configured to acquire, as the operation status signal, temperature information indicating an ambient temperature of the power amplifier, frequency information indicating a carrier frequency of the amplification target signal, bias voltage information indicating a bias voltage of the power amplifier, or backoff information indicating backoff of the power amplifier.

6. A distortion compensation method comprising:
acquiring an amplification target signal which is a signal to which power amplification by a power amplifier is performed;
acquiring an operation status signal indicating an operation status of the power amplifier;
acquiring a signal in which distortion is added to the amplification target signal as a predistortion signal for performing compensation of distortion generated in the amplification target signal after the power amplification by the power amplifier on a basis of the amplification target signal and the operation status signal, and outputting the predistortion signal to the power amplifier; and
giving, when the amplification target signal and the operation status signal are input, the amplification target signal and the operation status signal to a learning model being trained to output a signal to which distortion for compensating distortion generated in the amplification target signal after the power amplification is performed, and acquiring the predistortion signal estimated by the learning model without training the learning model
wherein the learning model is implemented by a neural network, and in training, a time-series signal of the amplification target signal, the operation status signal, and the predistortion signal are given to the learning model as training data,
the learning model is trained to output the predistortion signal corresponding to the time-series signal of the amplification target signal and the operation status signal which have been input by calculating a weight addition of the time-series signal of the amplification target signal and the operation status signal on a basis of weight coefficients determined by learning of the predistortion signal included in the training data, and
the processing circuitry generates, when the amplification target signal is input, a time-series signal of the amplification target signal by delaying the amplification target signal by a predetermined sampling time in order, gives the time-series signal of the amplification target signal being generated and the operation status signal to the learning model, and acquires the predistortion signal estimated by the learning model.

7. A transmission device comprising:
a power amplifier to amplify power of an amplification target signal which is a signal to which power amplification is performed; and
a distortion compensation device to perform compensation of distortion generated in the amplification target signal after the power amplification by the power amplifier, wherein
the distortion compensation device comprises processing circuitry
to acquire the amplification target signal which is a signal to be power-amplified by the power amplifier,
to acquire an operation status signal indicating an operation status of the power amplifier,
to acquire a signal in which distortion is added to the amplification target signal as a predistortion signal for performing compensation of distortion generated in the amplification target signal after the power amplification by the power amplifier on a basis of the amplification target signal and the operation status signal, and to output the predistortion signal to the power amplifier, and
to give, when the amplification target signal and the operation status signal are input, the amplification target signal and the operation status signal to a learning model being trained to output a signal to which distortion for compensating distortion generated in the amplification target signal after the power amplification is performed, and acquire the predistortion signal estimated by the learning model without training the learning model,
wherein the learning model is implemented by a neural network, and in training, a time-series signal of the amplification target signal, the operation status signal, and the predistortion signal are given to the learning model as training data,
the learning model is trained to output the predistortion signal corresponding to the time-series signal of the amplification target signal and the operation status signal which have been input by calculating a weight addition of the time-series signal of the amplification target signal and the operation status signal on a basis of weight coefficients determined by learning of the predistortion signal included in the training data, and
the processing circuitry generates, when the amplification target signal is input, a time-series signal of the amplification target signal by delaying the amplification target signal by a predetermined sampling time in order, gives the time-series signal of the amplification target signal being generated and the operation status signal to the learning model, and acquires the predistortion signal estimated by the learning model.
